(19) United States
(12) Patent Application Publication
(10) Pub. No.: US 2004/0118444 A1
(43) Pub. Date: Jun. 24, 2004

(54) LARGE-AREA PHOTOVOLTAIC DEVICES AND METHODS OF MAKING SAME

(75) Inventors: Anil Raj Duggal, Niskayuna, NY (US); Aharon Yakimov, Niskayuna, NY (US)

Correspondence Address: GENERAL ELECTRIC COMPANY, GLOBAL RESEARCH, PATENT DOCKET RM. BLDG. K1-4A59, SCHENECTADY, NY, 12301-0008, US

(73) Assignee: GENERAL ELECTRIC COMPANY, Niksayuna, NY (US)

(21) Appl. No.: 10/248,140

(22) Filed: Dec. 20, 2002

(51) Int. Cl. H01L 31/00

(52) U.S. Cl. 136/244; 136/263; 438/80; 438/82

(57) ABSTRACT

An organic photovoltaic (“PV”) device comprises a plurality of organic PV cells connected in series to cover a large area. The organic PV device optionally has an electrical circuit element connected in parallel to each organic PV cell. The organic PV device allows for continued operation even when short circuits develop or electrical interruption occurs in one of the cells. The device is conveniently manufactured using a shadow mask, which allows for the formation of several consecutive layers in one apparatus.

### BACKGROUND OF INVENTION

The present invention relates to optically absorptive photonic devices. In particular, the present invention relates to photovoltaic (“PV”) devices having large areas and methods of making the same.

Semiconductive PV devices are based on the separation of electron-hole pairs formed following the absorption of a photon. An electric field is generally required for the separation of the charges. The electric field may arise from a Schottky contact where a built-in potential exists at a metal-semiconductor interface or from a p-n junction between p-type and n-type semiconducting materials. Such devices are commonly made from inorganic semiconductors, especially silicon, which can have monocrystalline, polycrystalline, or amorphous structure. Silicon is normally chosen because of its relatively high photon conversion efficiency. However, silicon technology has associated high costs and complex manufacturing processes, resulting in devices that are expensive in relation to the power they produce.

Organic PV devices, which are based on active semiconducting organic materials, have recently attracted more interest as a result of advances made in organic semiconducting materials. These materials offer a promise of better efficiency that had not been achieved with earlier organic PV devices. Typically, the active component of an organic PV device comprises at least two layers of organic semiconducting materials disposed in contact with one another. The first organic semiconducting material is an electron acceptor, and the second an electron donor. An electron acceptor is a material that is capable of accepting electrons from another adjacent material due to a higher electron affinity of the electron acceptor. An electron donor is a material that is capable of accepting holes from an adjacent material due to a lower ionization potential of the electron donor. The absorption of photons in an organic photoconductive material results in the creation of bound electron-hole pairs, which must be dissociated before charge collection can take place. The separated electrons and holes travel through their respective acceptor (semiconducting material) to be collected at opposite electrodes.

In order to have a practical energy source from PV devices, large-area devices are needed to capture a large amount of sunlight. However, the manufacture of large-area defect-free PV devices is a challenge. Typically, a defect in the fabrication of a device, such as one that allows a short circuit, would render the whole device inoperative and useless.

Therefore, it is very desirable to provide PV devices that cover a large area, but are more tolerant to fabrication defects. It is also very desirable to provide large-area PV devices that remain operative and produce electrical energy even when there are microscopic short circuits in the originally made devices.

### SUMMARY OF INVENTION

According to one aspect of the present invention, an organic PV cell comprises at least one organic electron acceptor and at least one organic electron donor. The organic electron acceptor and the electron donor are disposed adjacent to one another to form a junction, and together are sandwiched between a pair of electrodes: a cathode and an anode. The cathode of one organic PV cell is electrically connected to the anode of an adjacent organic PV cell.

According to another aspect of the present invention, an electrical circuit element that is capable of providing a path for an electrical by-pass is connected in parallel to each of the organic PV cells.

According to another aspect of the present invention, a method is provided for making a large-area PV device. The method comprises: (a) forming a plurality of organic PV cells on a substrate, each cell comprising at least two organic semiconducting materials disposed between a pair of first and second electrodes; and (b) forming an electrical contact between the first electrode of one cell and the second electrode of an adjacent cell. The step of forming a plurality of organic PV cell comprises: (1) providing a plurality of distinct first electrodes on a substrate; (2) disposing a first layer of a first organic semiconducting material on each of the first electrodes, each of the first layers being separated from other first layers; (3) disposing a second layer of a second organic semiconducting material on each of the first layers, the first and second organic semiconducting materials forming a junction of an electron acceptor and an electron donor; and (4) disposing a second electrode on each of the layers of second organic semiconducting material.

According to still another aspect of the present invention, the method for making a large-area PV device comprises: (a) forming a plurality of separate organic PV cells, each cell comprising at least two organic semiconducting materials disposed between a pair of first and second electrodes; (b) disposing the plurality of the separate organic PV cells on a substrate; and (c) forming an electrical contact between the first electrode of one cell and the second electrode of another adjacent cell. The step of forming a separate organic PV cell comprises: (1) providing a first electrode layer; (2) disposing a first organic semiconducting material on the first electrode layer; (3) disposing a second organic semiconducting material on the first organic semiconducting material; and (4) disposing a second electrode layer on the second organic semiconducting material.

Other features and advantages of the present invention will be apparent from a perusal of the following detailed description of the invention and the accompanying drawings in which the same numerals refer to like elements.

### BRIEF DESCRIPTION OF DRAWINGS

FIG. 1 shows schematically a PV device comprising several PV cells connected in series.

FIG. 2 shows a side view of an embodiment of a PV device comprising several PV cells connected in series.

FIG. 3 shows a side view of a different embodiment of a PV device comprising several PV cells connected in series.

FIG. 4 shows schematically a PV device comprising several PV cells connected in series wherein a circuit element is connected in parallel to each PV cell.

FIG. 5 shows the steps of a method of making a PV device comprising several PV cells connected in series.

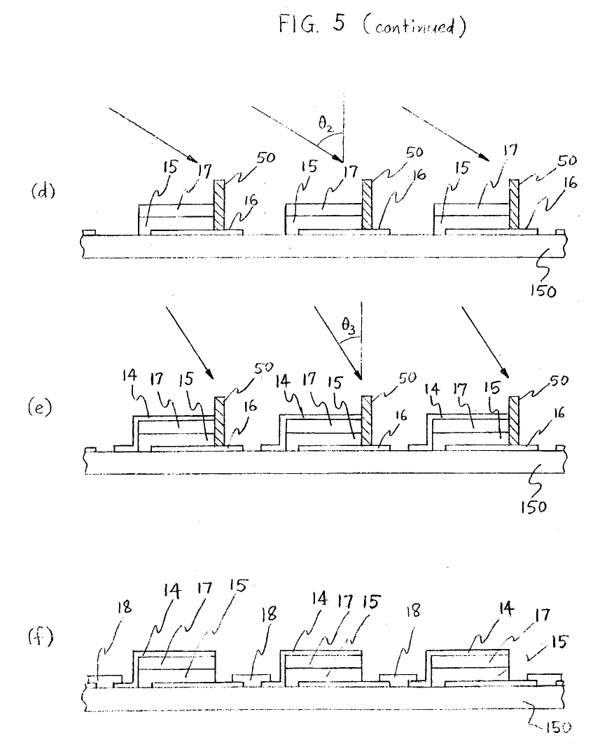

### DETAILED DESCRIPTION

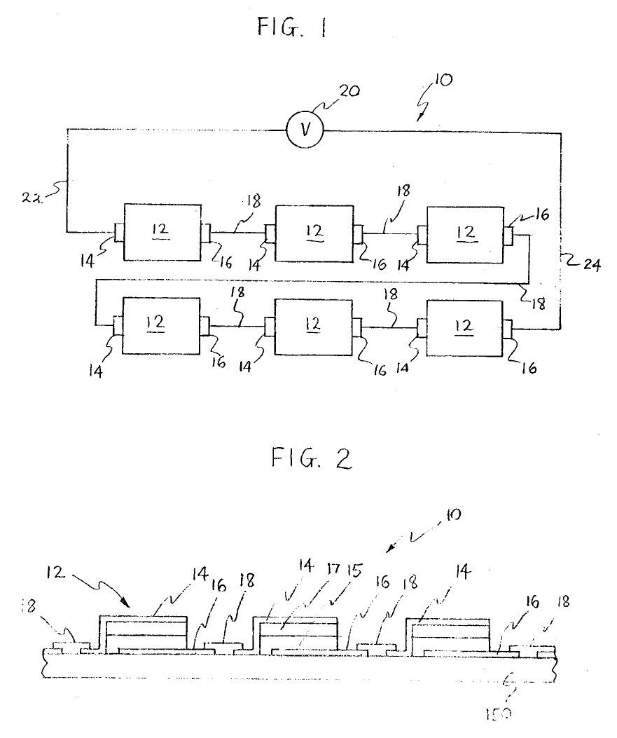

FIG. 1 illustrates a PV device according to a first embodiment of the present invention. It should be understood that the elements shown in the drawings are not drawn to scale. The PV device 10 of FIG. 1 includes a plurality of organic PV cells 12, which are connected in series and arranged to cover a large area. The term “large area” means an area greater than about 100 cm². For example, FIG. 1 illustrates six organic PV cells 12. However, the number of organic PV cells can be chosen as desired to cover an available area provided all cells are connected in series. The number of organic PV cells also can be chosen to provide a desired output potential V.

Each of the individual organic PV cells 12 has an anode 14 and a cathode 16. The organic PV cells 12 are electrically connected in a series arrangement; e.g., anode 14 to cathode 16, as shown in FIG. 1. In this regard, the respective anodes and cathodes may be electrically connected via interconnect wiring 18 as shown in FIG. 1. Each organic PV cell 12 is capable of absorbing photon energy and generating an electrical potential between its anode 14 and cathode 16. An output potential V from the plurality organic PV cells 12 is available at 20 between conducting line 22 connected to anode 14 of the first cell, and conducting line 14 connected to cathode 16 of the last cell in the series. Output potential V is the combined potential generated by all of the individual cells 12.

Furthermore, several groups of PV cells, each group comprising a plurality of PV cells connected in-series, can be connected together in any desired arrangement, such as in series or in parallel or a combination thereof, to provide an overall working PV device having a desired electrical potential.

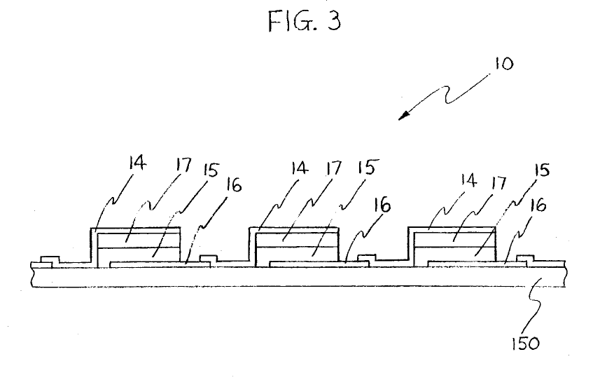

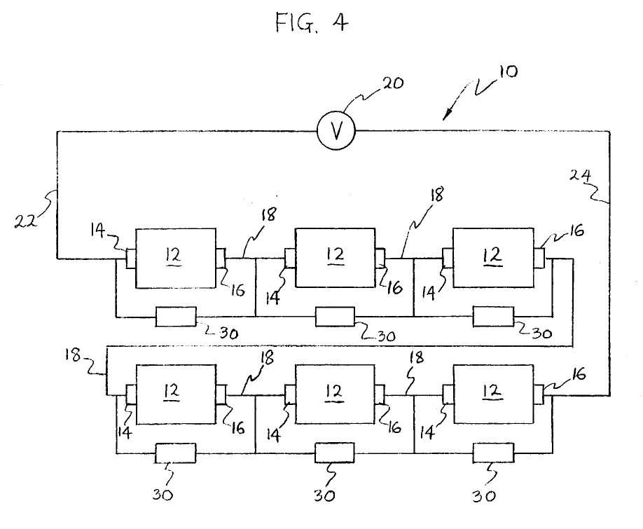

FIG. 2 shows a side view of a plurality of organic PV cells 12 connected in series and disposed on a substrate 150. Substrate 150 can be any electrically non-conducting material, such as glass, ceramic, wood, paper, or polymeric materials. Polymeric materials, such as polyesters, polycarbonates, poly(ethylene terephthalate) (“PET”), polyimides, polyetherimides, or silicones, are suitable. Cathodes 16 are provided on substrate 150, each cathode being separated from the other cathodes. A layer 15 of an organic semiconducting electron acceptor material is disposed on cathode 16, leaving a portion of cathode 16 uncovered for subsequent electrical connection. A layer 17 of an organic semiconducting electron donor material is disposed on layer 15. An anode layer 14 is disposed on layer 17. An electrical connection 18 comprising a high-conductivity material is formed to connect cathode 16 of one organic PV cell 12 to anode 14 of another adjacent organic PV cell. Alternatively, separate electrical connections 18 may be eliminated by extending anode 14 of a PV cell 12 to a cathode 16 of an adjacent PV cell, as illustrated in FIG. 3. It should be understood that the roles of the electrodes 14 and 16 can be reversed. In other words, electrode 14 can be an anode, and electrode 16 can be a cathode. In this case, layer 15 is an electron acceptor layer, and layer 17 is an electron donor layer. The group of PV cells 12 can further be protected by a substantially transparent protective barrier coating. The term “substantially transparent” means allowing at least 80 percent, preferably at least 90 percent, and more preferably at least 95 percent, of incident electromagnetic (“EM”) radiation to pass through a film having a thickness of about 0.5 micron at an incident angle less than about 10 degrees. The term “electromagnetic radiation” means electromagnetic radiation having wavelength in the range from ultraviolet (“UV”) to infrared (“IR”), such as from about 100 nm to about 1 mm. The organic semiconducting materials preferably absorb strongly in the wavelength range of sunlight. Suitable materials for each of the elements of the PV device are disclosed below.

Photons absorbed in organic semiconducting layers 15 and 17 produce excited electron-hole pairs (or excitons) that migrate to the junction between layers 15 and 17 where they dissociate into free electrons and holes, which migrate to the respective electrodes to be collected. The life time and diffusion length of excitons depend upon the nature of the organic semiconducting materials, but are typically very short. Exciton diffusion length has been estimated to be on the order of about 10 nm. The thicknesses of layers 15 and 17 ideally should not be much greater than the diffusion length, preferably smaller than about 100 nm. However, as the thicknesses of layers 15 and 17 decrease, the probability for short circuits through defects in the organic semiconducting layers increases. In addition, as the surface area of a cell increases, the probability for introducing defects into the cell also increases. Such defects can be in the form of, for example, pin holes, scratches, tears, conducting impurities, etc. When such a defect exists in such thin organic layers, a short circuit between electrodes 14 and 16 through the defect can easily occur. Such a short circuit renders a cell 12 inoperative because the charges will flow preferentially through the defect, and a charge separation will not result. Therefore, if a PV device consisting of only one large PV cell such that its surface area satisfies the energy requirement has a defect, the whole device will not produce energy. On the contrary, a PV device of the present invention comprising a plurality of PV cells connected in series avoids such a result. Even if one or more PV cells have short circuits, the remaining cells still are operative and produce electrical energy.

Alternatively, electrode 16 can be the anode, and electrode 14 can be the cathode. In this case, layer 17 comprises an electron acceptor material, and layer 15 comprises an electron donor material.

In another embodiment of the present invention, each organic PV cell further comprises one or more layers that enhance the transport of charges to the electrodes. For example, a layer of electron transport can be disposed between the cathode and the layer of electron acceptor material. Suitable materials for electron transport are metal organic complexes of 8-hydroxyquinoline, such as tris(8-quinolinolato) aluminum; stilbene derivatives; anthracene derivatives; perylene derivatives; metal thioxinoid compounds; oxadiazole derivatives and metal chelates; pyridine derivatives; pyrimidine derivatives; quinoline derivatives; quinoxaline derivatives; diphenylquinone derivatives; nitro-substituted fluorine derivatives; and triazines. A layer of hole transport material can be disposed between the anode and the electron donor layer. Suitable materials for hole transport are triaryidiamine, tetraphenyldiamine, aromatic tertiary amines, hydrazone derivatives, carbazole derivatives, triazole derivatives, imidazole derivatives, oxadiazole derivatives having an amino group, and polythiophene. The electron and hole transport materials may be deposited on the underlying layer by a method selected from the group consisting of physical vapor deposition, chemical vapor deposition, spin coating, and spraying, using a mask.

Another embodiment of the present invention is illustrated in FIG. 3. PV device 10 comprises a plurality of organic PV cells 12 connected in series. Each organic PV cell 12 comprises the elements disclosed above. In addition, a circuit element 30 is connected in parallel with an organic PV cell 12. Circuit element 30 provides an electrical by-pass to the associated organic PV cell when there is an interruption of charge flow to either the anode or the cathode of the organic PV cell through the organic semiconducting layers. Such an interruption can occur, for example, when there is a separation between two adjacent layers in the PV cell, such as between the organic semiconducting layers, or between an electrode and an adjacent organic semiconducting layer. Such a separation may be a defect resulting, for example, from the manufacturing, or from a long-term use of the organic PV cell. Circuit elements 30 are selected from the group consisting of resistors, diodes, varistors, and combinations thereof.

Modules, each comprising a plurality of organic PV cells connected in series, can be arranged to cover a desired large area to collect photon energy from sunlight, and generate electrical energy. It is desirable to mount the organic PV cells on flexible substrates, such as a polymeric film comprising one of the polymers disclosed above. Then the modules can be installed on surfaces of any curvature. In one embodiment, the modules can be installed on rooftops or outside walls of buildings.

Generally, the electrodes are made of materials having different work functions in order to induce an electric field across the PV cell. Cathode 16 is typically made of a metal having a low work function, such as one selected from the group consisting of K, Li, Na, Mg, La, Ce, Ca, Sr, Ba, Al, Ag, In, Sn, Zn, Zr, Sm, Eu, mixtures thereof, and alloys thereof. The cathode material can be deposited on substrate 150 to form separated cathodes 16 by physical vapor deposition, chemical vapor deposition, electron beam evaporation, sputtering, or electroplating, using a mask. Alternatively, a metal film can be deposited on the entire surface of substrate 150, and then is selectively etched to leave behind a pattern of cathodes 16. As another alternative, a negative pattern is formed on the substrate (for example, using photolithography), and the resultant pattern is subject to a plating treatment to produce the pattern of cathodes 16. Typically, the thickness of cathode 16 is in the range from about 10 nm to about 1000 nm.

Anode 16 is typically made of an electrically conducting material having a higher work function. In an embodiment in which incident EM radiation impinges on the anode side, anode 16 is made of a substantially transparent material, such as one selected from the group consisting of indium tin oxide (“ITO”), tin oxide, indium oxide, zinc oxide, indium zinc oxide, zinc indium tin oxide, antimony oxide, and mixtures thereof. Anode 16 can be deposited on the underlying layer by a method selected from the group consisting of physical vapor deposition, chemical vapor deposition, electron beam evaporation, sputtering, and electroplating, using a mask. Alternatively, a negative pattern is formed on the substrate (for example, using photolithography), and the resultant pattern is subject to a plating treatment to produce the pattern of anodes 14. A thin, substantially transparent layer of a metal is also suitable. Such a metal may be selected from the group consisting of Au, Co, Ni, Pt, mixtures thereof, and alloys thereof. The thickness of anode 14 is typically in the range from about 50 nm to about 400 nm, preferably from about 50 nm to about 200 nm.

Suitable electron acceptor materials for layer 15 are perylene tetracarboxidiimide, perylene tetracarboxidiimidazole, anthtraquinone acridone pigment, polycyclic quinone, naphthalene tetracarboxidiimidazole, CN- or CF₃-substituted poly (phenylene vinylene), and Buckminsterfullerene (C₆₀).

Suitable electron donor materials for layer 17 are metal-free phthalocyanine; phthalocyanine pigments containing copper, zinc, nickel, platinum, magnesium, lead, iron, aluminum, indium, titanium, scandium, yttrium, cerium, praseodymium, lanthanum, neodymium, samarium, europium, gadolinium, terbium, dysprosium, holmium, erbium, thulium, ytterbium, and lutetium; quinacridone pigment; indigo and thioindigo pigments; merocyanine compounds; cyanine compounds; squarylium compounds; hydrazone; pyrazoline; triphenylmethane; triphenylamine; conjugated electroconductive polymers, such as polypyrrole, polyaniline, polythiophene, polyphenylene, poly(phenylene vinylene), poly(thienylene vinylene), poly (isothianaphthalene); and poly(silane).

The thickness of layer 15 or 17 is typically in the range from about 5 nm to about 300 nm, preferably from about 10 nm to about 100 nm. The organic semiconducting material is typically deposited on the underlying layer by a method selected from the group consisting of vacuum deposition, spin coating, spraying, and ink-jet printing. The methods of vacuum deposition, spin coating, and spraying are conveniently carried out using a mask. The ink-jet printing can be carried out using a computer-aided design or computer-aided manufacturing software to control the locations where the material is laid down. Alternatively, a film of a an organic semiconducting material is deposited on the entire surface area, and then is patterned using a laser ablation method to leave behind material at desired locations. When the desired material is a polymer, its monomer can be deposited first, and then polymerized.

In another embodiment of the present invention, a group of organic PV cells connected in series can be protected from attack by reactive species in the environment, or from physical damage by providing a protective barrier coating disposed on the entire group. Such a protective barrier can advantageously comprise a plurality of alternating layers of at least an organic material and an inorganic material. For example, a layer of a polymer selected from the group consisting of polyacrylates, epoxy, silicone, silicone-functionalized epoxy, polycarbonates, and polyesters is first deposited on the entire group. The polymer can be deposited by a method selected from the group consisting of vacuum deposition, physical vapor deposition, chemical deposition, casting, spin coating, dip coating, and spraying. Then a layer of an inorganic material is deposited on the polymer layer by a method selected from the group consisting of physical vapor deposition, chemical vapor deposition, sputtering, electron beam deposition, and electroplating. Suitable inorganic materials for this layer are metals, metal nitrides, metal carbides, metal borides, metal oxides, and mixtures thereof. Alternatively, a protective barrier can comprise a polymer having low diffusion coefficients of reactive gases, such as oxidizing species and water vapor.

In one embodiment of the method of making a plurality of PV cells, successive layers 16, 15, 17, and 14 can be formed by a deposition method through a series of masks applied successively, each providing an appropriate pattern for the specific layer. Non-limiting examples of suitable deposition methods are physical vapor deposition, chemical vapor deposition, spin coating, spray coating, casting, sputtering, and electron beam vaporization. The method is selected to be compatible with the material deposited. Alternatively, the layers of PV cells can be formed by a combination of applying masks and selective patterning by, for example, cutting, etching, or ablating.

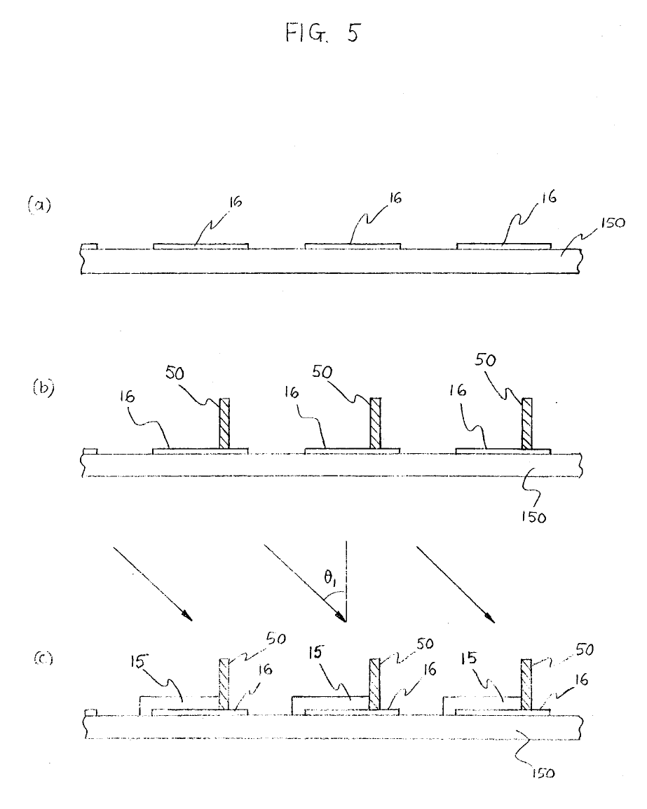

In another embodiment of the method of making a plurality of PV cells, layers 15 and 17 of organic semiconducting materials, and anode layer 14 are formed successively using a shadow mask. FIG. 4 shows the steps of such a method. First, a substrate 150 comprising one of the substrate materials disclosed above is provided in step (a). Substrate 150 has a plurality of distinct and separate first electrodes 16 formed thereon, such as by physical vapor deposition, chemical vapor deposition, sputtering, or electron beam deposition, using a mask. A layer of first electrode material may be deposited on the entire surface of substrate 150; then the layer is etched to form the first electrode pattern. In step (b), a plurality of walls 50 is formed on and near the edge of electrodes 16. One wall 50 is disposed on each electrode 16. Walls 50 can be formed from a negative-working photoresist composition, for example, by spin-coating and patterning by a photolithographic processing step. Walls 50 provide a shadow for the deposition of subsequent layers. In step (c), a first semiconducting material is deposited on electrodes 16 at an angle θ₁ with respect to a normal to the surface of substrate 150 to form a layer 15. For example, if first electrode 16 is a cathode, layer 15 comprises an electron acceptor. If first electrode 16 is an anode, layer 15 comprises an electron donor. In step (d), a second semiconducting material is deposited on layer 15 at an angle θ₂ to form layer 17. If layer 15 comprises an electron acceptor, layer 17 comprises an electron donor. If layer 15 comprises an electron donor, layer 17 comprises an electron acceptor. Angle θ₂ can be the same or different than angle θ₁. In step (e), a second electrode material is deposited on layer 17 at an angle θ₃ to form second electrode 14. Deposition using a show mask effect of walls 50, as disclosed here, reduces the effort in forming layers 15, 17, and 14. The work piece remains in place, and only the source of the deposited material and the deposition angle need be changed. Subsequently, walls 50 can be optionally removed by, for example, laser ablation or etching. In step (f), interconnects 18 are formed, each connecting first electrode 16 of a PV cell to second electrode 14 of an adjacent PV cell. Interconnects 18 can be formed by any suitable method, such as physical vapor deposition, chemical vapor deposition, sputtering, or electron beam deposition, using a mask.

Each of electrodes 16, walls 50, layers 15, 17, and 14, and interconnects 18 can be formed in strips extending across a first dimension of substrate 150. After all of the deposition steps are complete, the substrate having the layers formed thereon can be cut in the second dimension of substrate 150 to provide groups of PV cells connected in series.

While various embodiments are described herein, it will be appreciated from the specification that various combinations of elements, variations, equivalents, or improvements therein may be made by those skilled in the art, and are still within the scope of the invention as defined in the appended claims.

1. An organic photovoltaic (“PV”) device comprising a plurality of organic PV cells connected in series, each of said organic PV cell comprises:
a first electrode;
a second electrode;
at least first and second organic semiconducting materials disposed adjacent to one another to form a junction, said first organic semiconducting material being an electron donor material, said second organic semiconducting material being an electron acceptor material, and said organic semiconducting materials being disposed between said first and second electrodes;
wherein said first electrode of one PV cell is electrically connected to said second electrode of an adjacent PV cell.

2. The organic PV device according to claim 1, further comprising a circuit element connected in parallel to an organic PV cell, said circuit element being selected from the group consisting of resistors, diodes, varistors, and combinations thereof.

3. The organic PV device according to claim 1, wherein said first electrode is a cathode comprising a material selected from the group consisting of K, Li, Na, Mg, La, Ce, Ca, Sr, Ba, Al, Ag, In, Sn, Zn, Zr, Sm, Eu, mixtures thereof, and alloys thereof.

4. The organic PV device according to claim 1, wherein said first electrode is an anode comprising a material selected from the group consisting of substantially transparent metals and electrically conducting oxides.

5. The organic PV device according to claim 4, wherein said metals are Au, Co, Ni, Pt, mixtures thereof, and alloys thereof.

6. The organic PV device according to claim 4, wherein said electrically conducing oxides are indium tin oxide (“ITO”), tin oxide, indium oxide, zinc oxide, indium zinc oxide, zinc indium tin oxide, antimony oxide, and mixtures thereof.

7. The organic PV device according to claim 1, wherein said electron donor material is selected from the group consisting of metal-free phthalocyanine; phthalocyanine pigments containing copper, zinc, nickel, platinum, magnesium, lead, iron, aluminum, indium, titanium, scandium, yttrium, cerium, praseodymium, lanthanum, neodymium, samarium, europium, gadolinium, terbium, dysprosium, holmium, erbium, thulium, ytterbium, and lutetium; quinacridone pigment; indigo and thioindigo pigments; merocyanine compounds; cyanine compounds; squarylium compounds; hydrazone; pyrazoline; triphenylmethane; triphenylamine; conjugated electroconductive polymers, such as polypyrrole, polyaniline, polythiophene, polyphenylene, poly (phenylene vinylene), poly(thienylene vinylene), poly(isothianaphthalene); and poly(silane).

8. The organic PV device according to claim 1, wherein said electron acceptor material is selected from the group consisting of perylene tetracarboxidiimide, perylene tetracarboxidiimidazole, anthtraquinone acridone pigment, polycyclic quinone, naphthalene tetracarboxidiimidazole, CN- and CF₃-substituted poly (phenylene vinylene), and Buckminsterfullerene.

9. The organic PV device according to claim 3, wherein said electron acceptor material is disposed adjacent to said cathode, and each of said organic PV cells further comprises an electron transport material disposed between said cathode and said electron acceptor material.

10. The organic PV device according to claim 9, wherein said electron transport material is selected from the group consisting of metal organic complexes of 8-hydroxyquinoline; stilbene derivatives; anthracene derivatives; perylene derivatives; metal thioxinoid compounds; oxadiazole derivatives and metal chelates; pyridine derivatives; pyrimidine derivatives; quinoline derivatives; quinoxaline derivatives; diphenylquinone derivatives; nitro-substituted fluorine derivatives; and triazines.

11. The organic PV device according to claim 4, wherein said electron donor material is disposed adjacent to said anode, and each of said organic PV cells further comprises an hole transport material disposed between said anode and said electron acceptor material.

12. The organic PV device according to claim 11, wherein said hole transport material is selected from the group consisting of triaryldiamine, tetraphenyldiamine, aromatic tertiary amines, hydrazone derivatives, carbazole derivatives, triazole derivatives, imidazole derivatives, oxadiazole derivatives having an amino group, and polythiophene.

13. The organic PV device according to claim 1, wherein said plurality of organic PV cells are disposed on a substantially transparent substrate.

14. An organic PV device comprising a plurality of organic PV cells connected in series, each of said organic PV cell comprises:
a cathode;
a layer of at least an organic semiconducting electron acceptor material disposed adjacent to said cathode;
a layer of at least an organic semiconducting material electron donor material disposed adjacent to said electron acceptor material to form a junction; and
an anode disposed adjacent to said electron donor material;
wherein said cathode of one PV cell is electrically connected to said anode of an adjacent PV cell; said cathode comprises a material selected from the group consisting of K, Li, Na, Mg, La, Ce, Ca, Sr, Ba, Al, Ag, In, Sn, Zn, Zr, Sm, Eu, mixtures thereof, and alloys thereof; said anode comprises a material selected from the group consisting of substantially transparent metals, and substantially transparent electrically conducting oxides; said electron donor material is selected from the group consisting of metal-free phthalocyanine; phthalocyanine pigments containing copper, zinc, nickel, platinum, magnesium, lead, iron, aluminum, indium, titanium, scandium, yttrium, cerium, praseodymium, lanthanum, neodymium, samarium, europium, gadolinium, terbium,dysprosium, holmium, erbium, thulium, ytterbium, and lutetium; quinacridone pigment; indigo and thioindigo pigments; merocyanine compounds; cyanine compounds; squarylium compounds; hydrazone; pyrazoline; triphenylmethane; triphenylamine; conjugated electroconductive polymers, such as polypyrrole, polyaniline, polythiophene, polyphenylene, poly (phenylene vinylene), poly(thienylene vinylene), poly(isothianaphthalene); and poly(silane); and said electron acceptor material is selected from the group consisting of perylene tetracarboxidiimide, perylene tetracarboxidiimidazole, anthtraquinone acridone pigment, polycyclic quinone, naphthalene tetracarboxidiimidazole, CN- and CF₃-substituted poly(phenylene vinylene), and Buckminsterfullerene.

15. The organic PV device according to claim 14; wherein each of said organic PV cell further comprises an electron transport material disposed between said cathode and said electron acceptor material, and a hole transport material disposed between said anode and said electron donor material; said electron transport material being selected from the group consisting of metal-free phthalocyanine; phthalocyanine pigments containing copper, zinc, nickel, platinum, magnesium, lead, iron, aluminum, indium, titanium, scandium, yttrium, cerium, praseodymium, lanthanum, neodymium, samarium, europium, gadolinium, terbium, dysprosium, holmium, erbium, thulium, ytterbium, and lutetium; quinacridone pigment; indigo and thioindigo pigments; merocyanine compounds; cyanine compounds; squarylium compounds; hydrazone; pyrazoline; triphenylmethane; triphenylamine; conjugated electroconductive polymers, such as polypyrrole, polyaniline, polythiophene, polyphenylene, poly (phenylene vinylene), poly(thienylene vinylene), poly(isothianaphthalene); and poly(silane); and said hole transport material being selected from the group consisting of triaryldiamine, tetraphenyldiamine, aromatic tertiary amines, hydrazone derivatives, carbazole derivatives, triazole derivatives, imidazole derivatives, oxadiazole derivatives having an amino group, and polythiophene.

16. A method for making an organic PV device that comprises a plurality of organic PV cells connected in series, said method comprising forming a plurality of said organic PV cells, said forming each of said organic PV cells comprising:
providing a first electrode;
disposing a first organic semiconducting material on said first electrode;
disposing a second organic semiconducting material on said first organic semiconducting material to form a junction between said semiconducting materials; and
disposing a second electrode on said second organic semiconducting material, with a proviso that when said first organic semiconducting material is an electron donor, said second organic semiconducting material is an electron acceptor, and when said first organic semiconducting material is an electron acceptor, said second organic semiconducting material is an electron donor, said disposing said second electrode being carried out such that said second electrode makes an electrical contact with a first electrode of an adjacent PV cell.

17. A method for making an organic PV device that comprises a plurality of organic PV cells connected in series, said method comprising:
(a) forming a plurality of said organic PV cells, said forming each of said organic PV cells comprising:
(1) providing a first electrode;
(2) disposing a first organic semiconducting material on said first electrode;
(3) disposing a second organic semiconducting material on said first organic semiconducting material to form a junction between said semiconducting materials; and
(4) disposing a second electrode on said second organic semiconducting material, with a proviso that when said first organic semiconducting material is an electron donor, said second organic semiconducting material is an electron acceptor, and when said first organic semiconducting material is an electron acceptor, said second organic semiconducting material is an electron donor; and
(b) providing an electrical connection between said first electrode of an organic PV cell and said second electrode of an adjacent organic PV cell.

18. The method according to claim 17, wherein said disposing said first organic semiconducting material and said disposing said second organic semiconducting material are independently selected from the group consisting of vacuum deposition, spin coating, spraying, and ink-jet printing.

19. The method according to claim 17, wherein said disposing said second electrode is selected from the group consisting of physical vapor deposition, chemical vapor deposition, electron beam evaporation, sputtering, and electroplating.

20. The method according to claim 17, further comprising disposing an electron transport material between an electron acceptor material and an adjacent electrode.

21. The method according to claim 17, further comprising disposing a hole transport material between an electron donor material and an adjacent electrode.

22. A method for making an organic PV device that comprises a plurality of organic PV cells connected in series, said method comprising:
providing a plurality of distinct and separate first electrodes on a substrate;
disposing a first layer of a first organic semiconducting material on said plurality of said first electrodes;
disposing a second layer of a second organic semiconducting material on said first layer of said first organic semiconducting material, with a proviso that when said first organic semiconducting material is an electron donor, said second organic semiconducting material is an electron acceptor, and when said first organic semiconducting material is an electron acceptor, said second organic semiconducting material is an electron donor;
removing portions of said first and second semiconducting materials to leave patches on said first electrodes, each of said patches comprising both first and second organic semiconducting materials, and each patch overlapping with one of said first electrodes;
disposing a second electrode on each of said patches; and
providing an electrical connection between one first electrode and one adjacent second electrode, said one first electrode and said one adjacent second electrode being in contact with different patches of organic semiconducting materials.

23. A method for making an organic PV device that comprises a plurality of organic PV cells connected in series, said method comprising:
providing a plurality of distinct and separate first electrodes on a substrate;
forming a plurality of walls on said plurality of first electrodes, each wall being positioned near an edge of one first electrode;
providing a stream of a first organic semiconducting material at a first angle with respect to a normal to a surface of said substrate to deposit a layer of said first organic semiconducting material on a portion of each of said first electrodes;
providing a stream of a second organic semiconducting material at a second angle with respect to said normal to said surface of said substrate to deposit a layer of said second organic semiconducting material on said first organic semiconducting material, forming a stack of organic layers, with a proviso that when said first organic semiconducting material is an electron donor, said second organic semiconducting material is an electron acceptor, and when said first organic semiconducting material is an electron acceptor, said second organic semiconducting material is an electron donor;
providing a stream of a second electrode material at a third angle with respect to said normal to said surface of said substrate to form a second electrode on said second organic semiconducting material; and
disposing an electrical contact between said first electrode and an adjacent second electrode, said first electrode and said adjacent electrode being in contact with different stacks of organic layers.

24. A method for generating an electrical potential, said method comprising:
(a) providing a group of a plurality of organic PV cells connected in series; each of said organic PV cells comprising:
(1) a first electrode;
(2) a second electrode; and
(3) at least first and second organic semiconducting materials disposed adjacent to one another to form a junction, said first organic semiconducting material being an electron donor material, said second organic semiconducting material being an electron acceptor material, and said organic semiconducting materials being disposed between said first and second electrodes;
wherein said first electrode of one PV cell is electrically connected to said second electrode of an adjacent PV cell;
(b) providing electromagnetic (“EM”) radiation to at least a surface of said plurality of said organic PV cells; and
(c) obtaining said electrical potential between said first electrode of a first PV cell in said group and said second electrode of a last PV cell in said group.

25. The method according to claim 24, wherein said EM radiation has a wavelength range from about 100 nm to about 1 mm.

26. A method for generating an electrical potential, said method comprising:
(a) providing a group of a plurality of organic PV cells connected in series; each of said organic PV cell having an electrical circuit element connected in parallel thereto; each of said organic PV cells comprising:
(1) a first electrode;
(2) a second electrode; and
(3) at least first and second organic semiconducting materials disposed adjacent to one another to form a junction, said first organic semiconducting material being an electron donor material, said second organic semiconducting material being an electron acceptor material, and said organic semiconducting materials being disposed between said first and second electrodes;
wherein said first electrode of one PV cell is electrically connected to said second electrode of an adjacent PV cell;
(b) providing EM radiation to at least a surface of said plurality of said organic PV cells; and
(c) obtaining said electrical potential between said first electrode of a first PV cell in said group and said second electrode of a last PV cell in said group.

27. The method according to claim 26, wherein said EM radiation has a wavelength range from about 100 nm to about 1 mm.
